(19) United States
(12) Patent Application Publication
(10) Pub. No.: US 2014/0362548 A1
(43) Pub. Date: Dec. 11, 2014

(54) CHIP CARD HOLDER FOR ELECTRONIC DEVICE

(71) Applicants: FIH (Hong Kong) Limited, Kowloon (HK); SHENZHEN FUTAIHONG PRECISION INDUSTRY CO., LTD., Shenzhen (CN)

(72) Inventors: ZHEN-LIN LIU, Shenzhen (CN); HUI-TAO QIU, Shenzhen (CN); WEN-ZE LIU, Shenzhen (CN)

(73) Assignees: FIH (Hong Kong) Limited, Kowloon (HK); SHENZHEN FUTAIHONG PRECISION INDUSTRY CO., LTD., Shenzhen (CN)

(21) Appl. No.: 14/068,895

(22) Filed: Oct. 31, 2013

(30) Foreign Application Priority Data
Jun. 11, 2013 (CN) 2013102302406

(51) Int. Cl. H05K 5/00; H05K 5/02; G06F 1/16

(52) U.S. Cl. CPC H05K 5/0091; G06F 1/16; H05K 5/0086; H05K 5/0221
USPC 361/754; 312/333

(57) ABSTRACT

A chip card holder includes a housing, a receiving frame, a tray, and a pin. The housing defines a latching groove. The receiving frame is mounted to the housing, and the receiving frame includes at least one ejecting arm. The tray is slidably received in the receiving frame and defines a receiving groove configured for receiving a chip card. The tray includes a latching tongue. When the tray is received in the receiving frame, the latching tongue is latched in the latching groove, and the ejecting arm abuts against one end of the tray. The pin deforms the latching tongue to unlock the tray from the housing.

### BACKGROUND

1. Technical Field

The present disclosure generally relates to electronic cards of electronic devices, and particularly to a chip card holder for an electronic device.

2. Description of Related Art

With the development of wireless communication and information processing technologies, portable electronic devices such as mobile phones are widely used. Chip cards having special circuits are used in portable electronic devices to enhance or add to the functions of the portable electronic devices.

Although chip card holders are simple, it can be difficult to remove the chip card from the chip card holder.

Therefore, there is room for improvement within the art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the chip card holder. Moreover, in the drawings, like reference numerals designate corresponding parts throughout the several views.

FIG. 1 is an exploded view of one embodiment of a chip card holder.

FIG. 2 is similar to FIG. 1, but viewed from anther aspect.

FIG. 3 is an enlarged view of portions of the chip card holder.

FIG. 4 is an assembled view of the chip card holder.

FIG. 5 is a cross-sectional view taken along line V-V of FIG. 4.

FIG. 6 is similar to FIG. 5, but shows an unlocked state of the chip card holder.

### DETAILED DESCRIPTION

The disclosed surface contact card holder can seat chip cards such as SIM cards, compact flash cards (CFs) and multimedia cards (MMCs), for example. The disclosed electronic device in the exemplary embodiment is a mobile phone and can alternatively be a personal digital assistant (PDA), camera, recorder, or other device, while remaining within the scope of the disclosure.

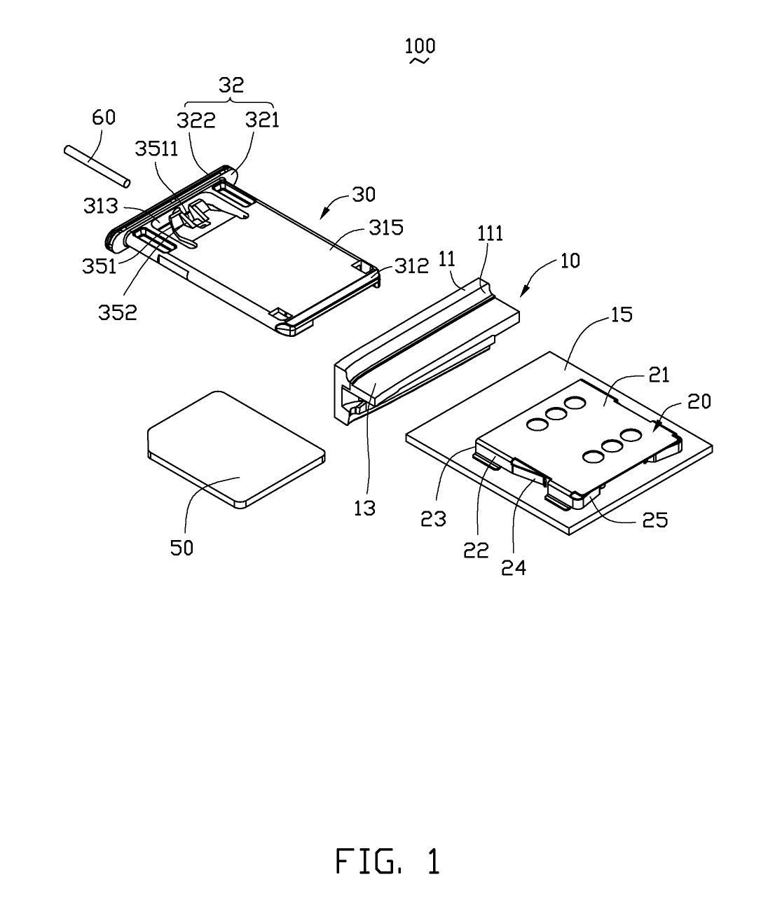

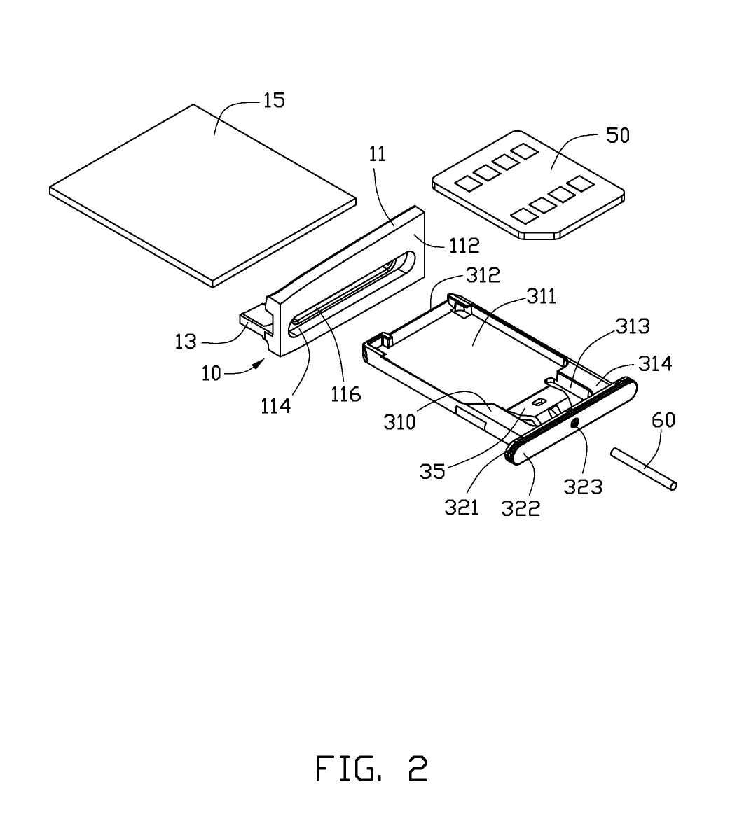

FIGS. 1 and 2 show a chip card holder 100 for receiving a chip card 50. The chip card holder 100 includes a housing 10, a receiving frame 20, a tray 30, and a pin 60. The tray 30 slidably engages with the receiving frame 20 for latching the chip card 50 in the housing 10. The pin 60 unlocks the tray 30 from the receiving frame 20 to remove the chip card 50.

The housing 10 may be a portion of the portable electronic device or a separate element fixed to the portable electronic device. In this exemplary embodiment, the housing 10 is a top portion or a bottom portion of the portable electronic device. The housing 10 includes an end wall 11 and a plate body 13 integrated with the end wall 11. The end wall 11 includes an interior surface 111 and an exterior surface 112. A first hole 114 is defined in the exterior surface 112, and a second hole 116 is defined in the interior surface 111. The first hole 114 and the second hole 116 communicate with each other.

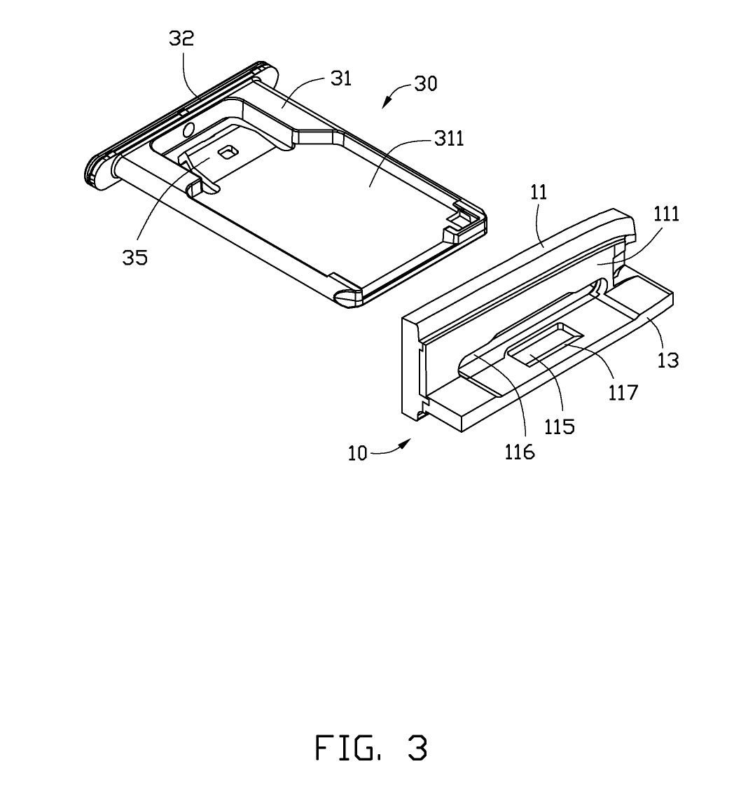

Referring to FIG. 3, the plate body 13 extends from the interior surface 111. One surface of the plate body 13 defines a latching groove 115. The latching groove 115 is configured for latching the tray 30. In this exemplary embodiment, the latching groove 115 forms a guiding slope 117. The guiding slope 117 slopes from a sidewall of the latching groove 115 toward a bottom surface of the latching groove 115. A printed circuit board 15 (PCB) is received in the housing 10.

The receiving frame 20 is secured on the PCB 15 and is aligned with the first hole 114 and the second hole 116. The receiving frame 20 is made of metal and includes a frame body 21 and two opposite flanges 22 extending toward a same direction from opposite side edges of the frame body 21, respectively, thereby cooperatively defining a receiving cavity. An entrance 23 is defined at one end of the frame body 21 for receiving the tray 30. An elastic latching arm 24 extends from each flange 22 for engaging with opposite sides of the tray 30. Two opposite ejecting arms 25 extend from one end of the receiving frame 20 opposite to the entrance 23.

The tray 30 has a tray body 31 and a tray cap 32. The tray body 31 is received through the second hole 16, and the tray cap 32 is received in the first hole 114 for covering the first hole 114. The tray body 31 is made of plastic and has a first surface 310 and a second surface 315. A receiving groove 311 is defined in the first surface 310 for receiving the chip card 50. The tray 30 has a first end 312 and a second end 314 opposite to the first end 312. The tray cap 32 is formed on the first end 312. The first end 312 abuts against the ejecting arms 25 when the tray 30 is received in the receiving frame 20. The second end 314 defines a notch 313, and a latching tongue 35 extends into the notch 313. The latching tongue 35 selectively latches in the latching groove 115 for latching the tray 30 to the housing 10. The tray cap 32 includes a metal portion 322 and a plastic portion 321. The plastic portion 321 is integrally formed with the tray body 11 by injection molding. The metal portion 322 is formed on the plastic portion 321 by insert molding. A through hole 323 is defined through the metal portion 322 and the plastic portion 321. The through hole 323 allows the pin 60 to extend therethough.

The latching tongue 35 is latched in the latching groove 115. A free end of the latching tongue 35 includes two hooks 351, two stopper blocks 352, and an arcuate guiding portion 356. A guiding groove 3511 is defined between the two hooks 351. Each stopper block 352 is formed at one side of a corresponding hook 351, and the guiding portion 356 is formed between the two stopper blocks 352. The guiding groove 3511 is aligned with the through hole 323. When one end of the pin 60 is received in the through hole 323 and extends through the guiding groove 3511, the end of the pin 60 elastically abuts against the guiding portion 356 for deforming the latching tongue 35 to unlock the latching tongue 35 from the housing 10.

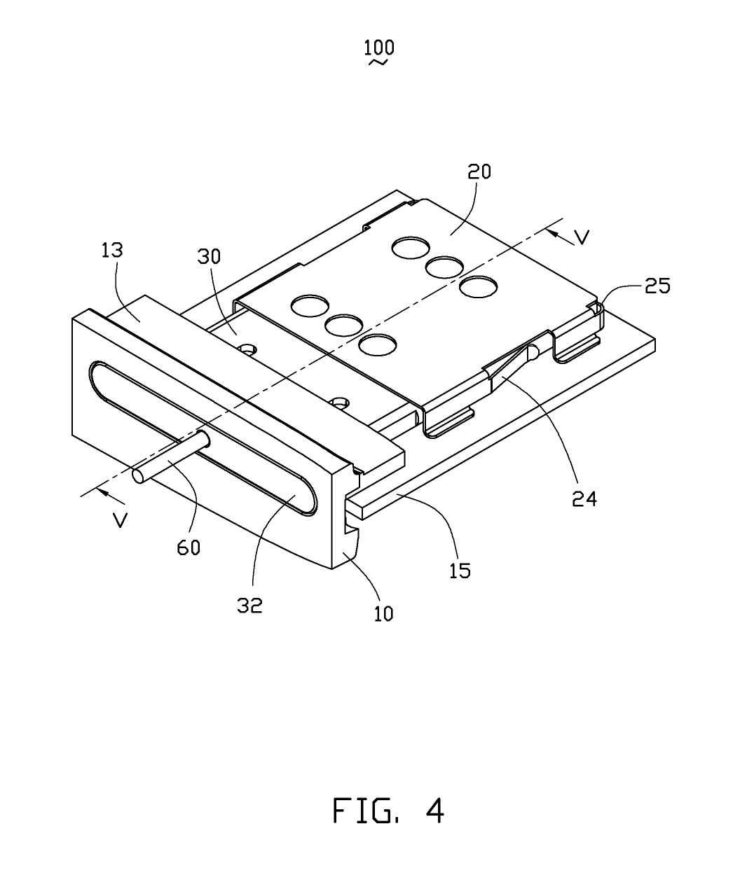

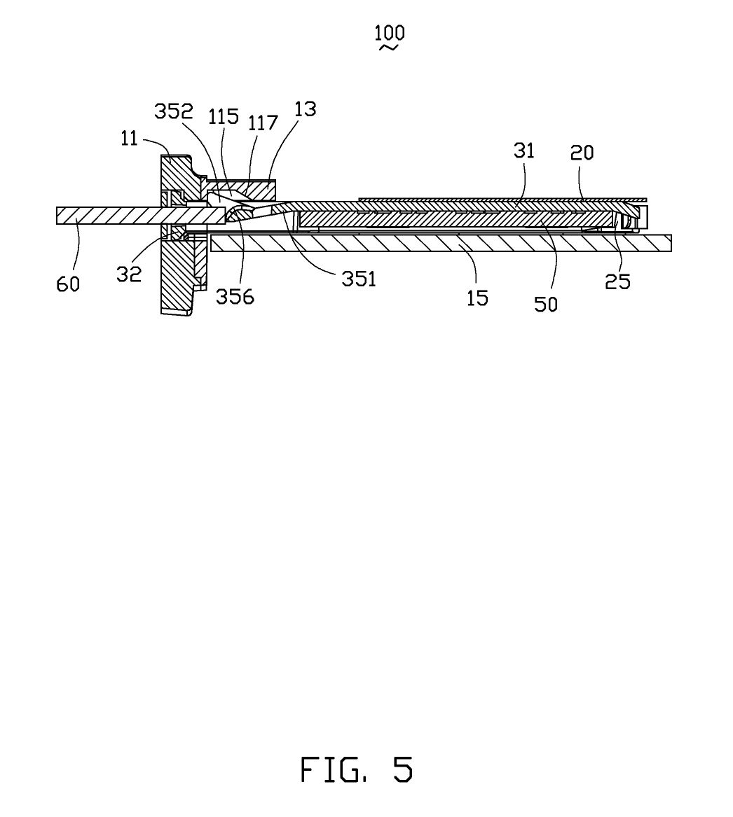

Referring to FIGS. 4 and 5, in assembly, the receiving frame 20 is mounted to the PCB 15. The chip card 50 is received in the receiving groove 311. The tray body 31 with the chip card 50 is received in the receiving frame 20 through the first hole 114 and the second hole 116 until the tray cap 32 covers the first hole 114. The latching arms 24 elastically latch with opposite sides of the tray body 31, and the ejecting arms 25 elastically abut against the first end 312. The hooks 351 of the latching tongue 35 are latched in the latching groove 115. The stopper blocks 352 abut against the guiding slope 17. Thus, the tray 30 is assembled in the housing 10.

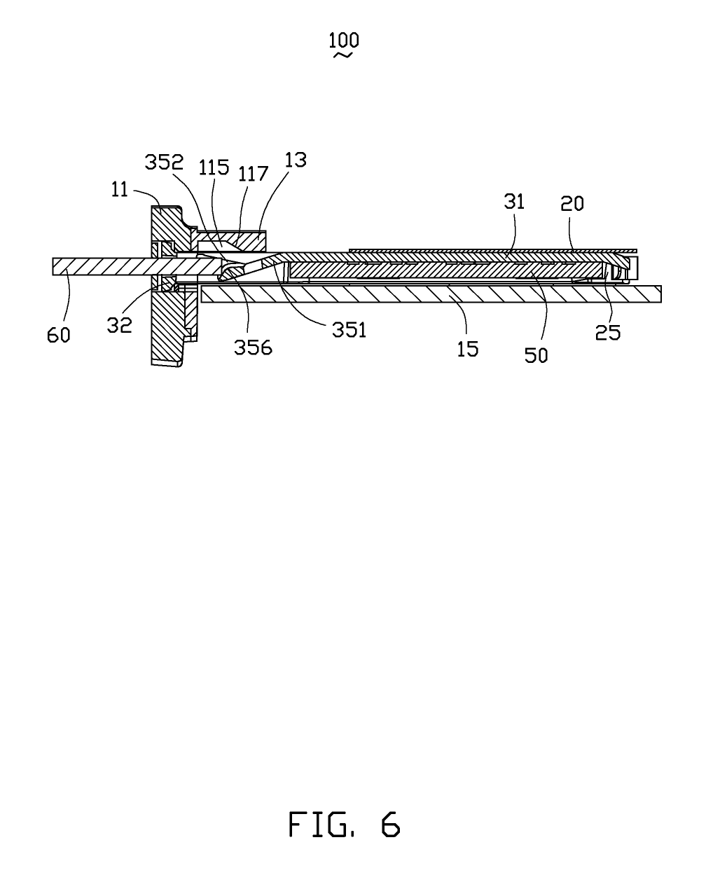

Referring to FIG. 6, to take out the chip card 50, the pin 60 is inserted into the through hole 323 and extends through the guiding groove 3511, until the pin 60 abuts against the guiding portion 356. The guiding portion 356 guides the pin 60 to further press the latching tongue 35. Thus, the latching tongue 35 deforms and detaches from the latching groove 115. Thus, the tray 30 is unlocked from the housing 10, and the ejecting arms 25 restore to eject the tray 30 from the housing 10. Thus, the chip card 50 can be easily removed from the housing 10.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A chip card holder, comprising:
a housing defining a latching groove;
a receiving frame mounted to the housing, the receiving frame including at least one ejecting arm; and
a tray slidably received in the receiving frame, the tray defining a receiving groove and comprising a latching tongue, the receiving groove configured for receiving a chip card;
a pin;
wherein when the tray is received in the receiving frame, the latching tongue is latched in the latching groove, and the at least one ejecting arm abuts against one end of the tray, the pin deforms the latching tongue to unlock the tray from the housing.

2. The chip card holder as claimed in claim 1, wherein the tray has a tray body and a tray cap, the tray body defines the receiving groove, one end of the tray body opposite to the tray cap defines a notch, and the latching tongue extends into the notch.

3. The chip card holder as claimed in claim 2, wherein the tray cap includes a metal portion and a plastic portion, the plastic portion is integrally formed with the tray body by injection molding, and the metal portion is formed with the plastic portion by insert molding.

4. The chip card holder as claimed in claim 3, wherein the tray cap defines a through hole for communicating with the metal portion and the plastic portion, and the through hole allows the pin to extend therethough.

5. The chip card holder as claimed in claim 1, wherein the latching tongue includes two hooks, two stopper blocks, and an arcuate guiding portion, a guiding groove is defined between the two hooks, each stopper block is formed at one side of each hook, and the arcuate guiding portion is formed between the two stopper blocks.

6. The chip card holder as claimed in claim 1, wherein the receiving frame includes a frame body and two opposite flanges, an entrance is defined at one end of the frame body to allow the tray to be inserted into receiving frame.

7. The chip card holder as claimed in claim 6, wherein each flange has an elastic latching arm for engaging with opposite sides of the tray, the at least one ejecting arm extends from one end of the receiving frame opposite to the entrance.

8. A portable electronic device comprising:
a housing defining a latching groove;
a printed circuit board;
a receiving frame mounted to the printed circuit board;
a tray slidably received in the receiving frame, the tray defining a receiving groove and comprising a latching tongue latched in the latching groove, the receiving groove configured for receiving a chip card; and
a pin;
wherein the pin deforms the latching tongue to disengage the latching tongue from the latching groove for unlocking the tray from the housing.

9. The portable electronic device as claimed in claim 8, wherein the housing includes an end wall and a plate body integrated with the end wall, and one surface of the plate body defines the latching groove.

10. The portable electronic device as claimed in claim 9, wherein the receiving frame includes a frame body and two opposite flanges, an entrance is defined at one end of the frame body to allow the tray to be inserted into receiving frame.

11. The portable electronic device as claimed in claim 10, wherein each flange has an elastic latching arm for engaging with opposite sides of the tray, and the at least one ejecting arm extends from one end of the receiving frame opposite to the entrance.

12. The portable electronic device as claimed in claim 8, wherein the latching tongue includes two hooks, two stopper blocks, and an arcuate guiding portion, a guiding groove is defined between the two hooks, each stopper block is formed at one side of each hook, and the arcuate guiding portion is formed between the two stopper blocks.

13. The portable electronic device as claimed in claim 8, wherein the tray has a tray body and a tray cap, the tray body defines the receiving groove, one end of the tray body opposite to the tray cap defines a notch, the latching tongue extends into the notch.

14. The portable electronic device as claimed in claim 13, wherein the tray cap includes a metal portion and a plastic portion, the plastic portion is integrally formed with the tray body by injection molding, the metal portion is formed with the plastic portion by insert molding.

15. The portable electronic device as claimed in claim 14, wherein the tray cap defines a through hole for communicating with the metal portion and the plastic portion, the through hole allows the pin to extend therethough.
